(19) United States
(12) Patent Application Publication
(10) Pub. No.: US 2025/0160011 A1
(43) Pub. Date: May 15, 2025

(54) OPTICAL SENSOR PACKAGE

(71) Applicant: SEMICONDUCTOR COMPONENTS INDUSTRIES, LLC, Scottsdale, AZ (US)

(72) Inventor: Brian Patrick MCGARVEY, Templemartin (IE)

(73) Assignee: SEMICONDUCTOR COMPONENTS INDUSTRIES, LLC, Scottsdale, AZ (US)

(21) Appl. No.: 18/506,269

(22) Filed: Nov. 10, 2023

(51) Int. Cl. H01L 27/146; H01L 23/00

(52) U.S. Cl. CPC H10F 39/804; H01L 24/45; H01L 24/48; H01L 24/85; H10F 39/011; H01L 2224/45124; H01L 2224/45144; H01L 2224/45147; H01L 2224/48091; H01L 2224/48245; H01L 2224/85801

(57) ABSTRACT

An optical sensor module includes a glass lid that protects the sensor die, and a perimeter frame to secure the glass lid. The perimeter frame can hold the glass lid in a position suspended above the sensor die and spaced apart from the sensor die by an air gap. An epoxy seals the glass lid between the perimeter frame and the package. The addition of the perimeter frame creates a longer path length for moisture and gas penetration, preventing moisture from reaching the sensor die, while allowing light to enter the sensor die.

### TECHNICAL FIELD

This description relates to assembling and packaging semiconductor device modules, semiconductor device assemblies, and semiconductor devices. More specifically, this description relates to a semiconductor device module that includes a molded optical sensor.

### BACKGROUND

Semiconductor device assemblies, such as assemblies including optical sensors, e.g., image sensors such as silicon photomultipliers (SiPMs) and SiPM arrays, can be implemented using one or more semiconductor dies, one or more substrates, and electrical interconnections such as bond wires, conductive spacers and conductive clips. Known semiconductor device assemblies may have structural integrity issues that can prevent use in some electronic applications.

### SUMMARY

In some aspects, the techniques described herein relate to an apparatus, including: a lead frame; a semiconductor die coupled to the lead frame; an optically transparent lid spaced apart from the semiconductor die by a gap; a package surrounding the semiconductor die, the package configured to support a perimeter of the optically transparent lid, coupled thereto by a sealant; and a perimeter frame disposed on top of at least a portion of the perimeter of the optically transparent lid such that the optically transparent lid is fixedly coupled (e.g., held in place) between the perimeter frame and the package.

In some aspects, the techniques described herein relate to a method, including: forming a lead frame having a base and leads; attaching a semiconductor die to the base; coupling the semiconductor die to the leads using wire bonds; forming an optical package around the lead frame, the semiconductor die, and the wire bonds; covering the semiconductor die with a glass lid; disposing a perimeter frame over the glass lid; and securing the glass lid and the perimeter frame to the optical package.

In some aspects, the techniques described herein relate to a die package, including: a lead frame; a glass lid suspended above the lead frame; a perimeter frame over the glass lid; and a packaging material that is conformal with the lead frame, the glass lid, and the perimeter frame.

### BRIEF DESCRIPTION OF THE DRAWINGS

FIG. 1A is a cross-sectional view of an optical sensor module equipped with a perimeter frame, according to an implementation of the present disclosure.

FIG. 1B is a plan view of the optical sensor shown in FIG. 1A, according to an implementation of the present disclosure.

FIGS. 2, 3, and 4A are cross-sectional views of an optical sensor module equipped with different perimeter frame designs, according to implementations of the present disclosure.

FIG. 4B is a side elevation view of the perimeter frame shown in FIG. 4A, according to an implementation of the present disclosure.

FIG. 5 is a flow diagram illustrating a method of fabricating the optical sensor modules shown in FIGS. 1A, 1B, 2, 3, 4A and 4B, according to an implementation of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

Current implementations of semiconductor device assemblies such as, for example, an optical sensor module formed around an optical sensor die, e.g., an image sensor such as a CMOS image sensor that may include a silicon micro-lens array, may have certain drawbacks. For instance, current implementations may be assembled into a chip package that includes a transparent lid, e.g., a glass lid, above the optical sensor die. The transparent lid covers and protects the optical sensor while transmitting light to a central active area of the image sensor die. The transparent lid may also provide an air cavity over the micro-lens array at the silicon surface. One failure mode that can occur in such devices is a moisture ingress-related failure in which the transparent lid can separate from the chip package. The moisture resilience of the device depends on an adhesive epoxy layer between the transparent lid and the chip package. If the “glass-to-package” bond is not sufficiently rugged, the transparent lid can detach from the chip package during thermal events, e.g., due to warping of the package or due to expansion of air trapped in the cavity.

This disclosure relates to implementations of semiconductor device assemblies that include optical sensors, in which the package has a mechanical securing feature, in addition to an adhesive epoxy layer, to improve the ruggedness of the glass-to-package bond. Instead of forming the package by injection molding at the end of the fabrication process, the package can be formed earlier using a pre-molding process so that the package itself can be used as a structural support during assembly of the optical sensor module. Multiple adhesive layers can then be used to secure, and conform, the other structural components to the package.

In some implementations, a molding compound, e.g., an epoxy molding compound, can be used as an encapsulant to protect components of the semiconductor device assemblies described herein. An encapsulated semiconductor device assembly, or chip assembly, can be referred to as a packaged device or a semiconductor device module. Semiconductor device assemblies that include optical sensors, or light sensors, can be used in a number of image-processing applications, including cameras, smart phones, video surveillance equipment, infrared imaging systems, automotive systems including light detection and ranging (LiDAR), and industrial applications.

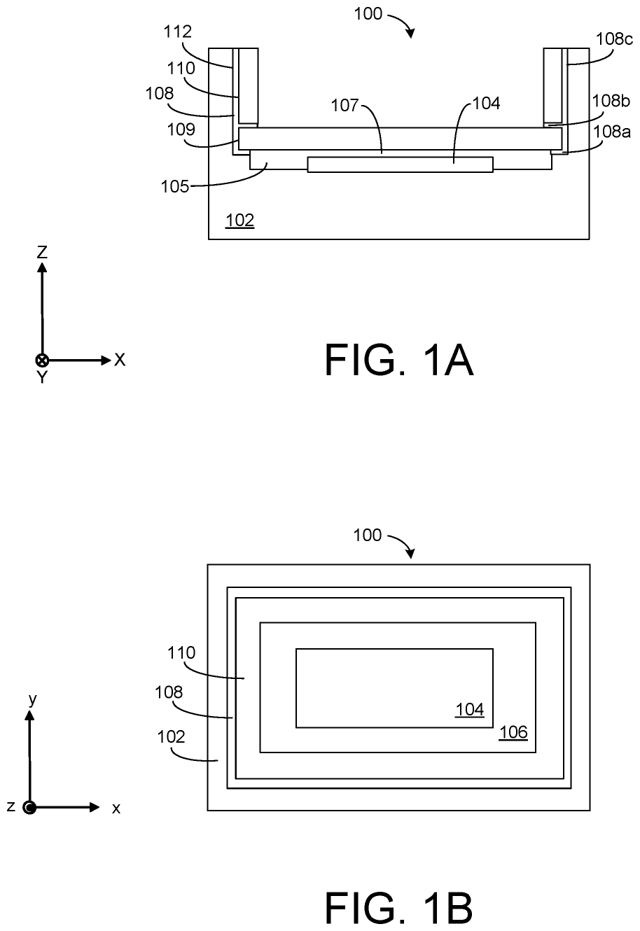

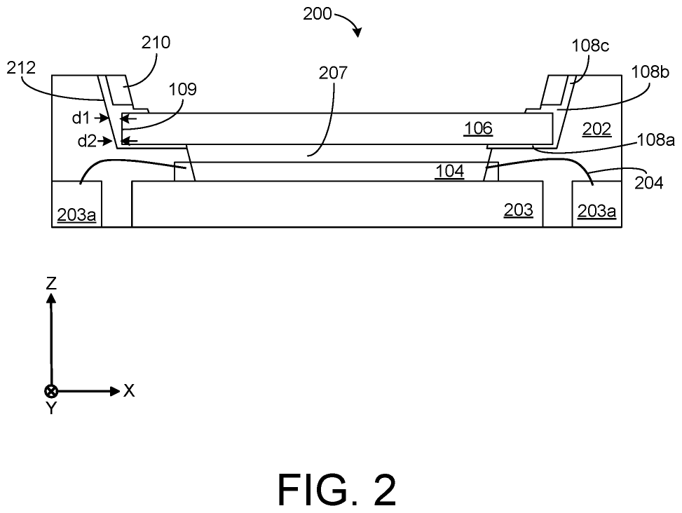

FIG. 1A is a cross-sectional view, and FIG. 1B is a top plan view, of an optical sensor module 100 equipped with a securing frame 110, in accordance with some implementations of the present disclosure. The optical sensor module 100 includes, in addition to the securing frame 110, a package 102, a sensor die 104, a cavity 105, a transparent lid 106, and an adhesive layer 108.

The package 102 consists of an encapsulant, e.g., a molding compound. In some implementations, the package 102 can be a pre-molded phenol-based epoxy package, a ceramic carrier package, or any open cavity optoelectronic sensor package. In some implementations, the package 102 can be fabricated using a film assist mold. In the example of FIG. 1A, a top portion of the package 102 has an inner sidewall profile that is substantially vertical. In some implementations, a lower portion of the inner sidewall 112 of the package 102 extends under a perimeter of the transparent lid 106 to provide support for the transparent lid 106. In some implementations, the package 102 can have outer dimensions in a range of about 3 mm to about 25 mm. In some implementations, the package 102 can have a height in a range of about 1.5 mm to about 6.0 mm.

In some implementations, the sensor die 104 can be a semiconductor die that includes an optical sensor such as a CMOS image sensor, that is, an image sensor that includes metal-oxide-semiconductor field effect transistors (MOSFETs) and related integrated circuit components. In some implementations, the sensor die 104 can include an optical sensor in the form of a silicon photomultiplier or a silicon photomultiplier array. In some implementations, the sensor die 104 can include a micro-lens array. The sensor die 104 can be attached to, e.g., disposed on, mounted to, coupled to, or in direct contact with, an upper surface of the package 102. An active area can be located in a central region of the sensor die 104. The active area can be a region formed on an epitaxial layer of the sensor die 104. The active area of the sensor die 104 may include electronic components configured with photosensitive elements to sense light, e.g., reflected light from a target, or external object, that will form a digital image of the target. In some implementations, a sensor within the active area on the sensor die 104 can have a thickness in a range of about 1 mm to about 20 mm.

In some implementations, the sensor die 104 can be formed on a substrate that includes a ceramic material, a glass material, a semiconductor material, an organic material, a resin material, a laminate, or a printed circuit board. In some implementations, the substrate can include a portion of a semiconductor wafer having integrated circuit components such as transistors and interconnects, e.g., layers of metallization, formed therein. For example, the substrate can be made of, or can include silicon, silicon carbide (SiC), or III-V semiconductor materials such as gallium arsenide (GaAs), indium phosphide (InP), and so forth. In some implementations, the substrate can be a glass substrate or a sapphire substrate.

The cavity 105 is formed around the sensor die 104. In some implementations, the cavity 105 is bounded above by the transparent lid 106 and laterally by the package 102. In some implementations, the cavity 105 can be an air cavity, or the cavity 105 can be filled with an inert gas such as nitrogen (N2) gas. The cavity 105 may include, e.g., provide, a gap 107, e.g., spacing, between the sensor die 104 and the transparent lid 106. Like the cavity 105, the gap 107 can be an air gap, or a gap filled with an inert gas such as nitrogen (N2) gas. The gap 107 can have a thickness, e.g., a vertical extent, in a range of about 0.02 mm to about 1.3 mm.

Light detected by the sensor die 104 can be received through the transparent lid 106, which may provide environmental protection for at least an active area of the sensor die 104. The transparent lid 106 can be made of glass or another optically transparent material, e.g., a polymer material that has suitable optical properties such as, for example, PMMA, acrylic, transparent forms of polyvinyl chloride (PVC), or similar materials. The transparent lid 106 is protected by the package 102, which wraps around sidewalls 109 of the transparent lid 106. In the example of FIG. 1, the vertical sidewalls 109 of the transparent lid 106 are conformal with vertical portions of the inner sidewall 112 of the package 102. The package 102 assists in preventing mechanical damage to the transparent lid 106. The package 102 can provide edge support for the transparent lid 106 to maintain a vertical position of the transparent lid 106 suspended above the sensor die 104 such that the air cavity 105 surrounds both the sides and top of the sensor die 104 so as to maintain the gap 107 separating the transparent lid 106 from the sensor die 104.

In some implementations, the adhesive layer 108 can be an adhesive film. In some implementations, the adhesive layer 108 can be a type of sealant, e.g., an epoxy, a thermoplastic epoxy, and/or an organic-based sealant. The adhesive layer 108 fills space between the inner sidewall 112 of the package 102 and the securing frame 110. The adhesive layer 108 also fills space between the inner sidewall 112 of the package 102 and the transparent lid 106. Further, the adhesive layer 108 fills space between the securing frame 110 and the perimeter of the transparent lid 106. The adhesive layer 108 thus provides a lengthened moisture penetration path that prevents moisture from reaching the sensor die 104, e.g., image sensor die, while allowing light to reach the image sensor.

In some implementations, the adhesive layer 108 includes different portions, e.g., a first adhesive layer 108a, a second adhesive layer 108b, and a third adhesive layer 108c that can be applied at different times and by different methods, during the fabrication process. The first adhesive layer 108a can be characterized as residing on horizontal surfaces of the package, e.g., the package 102; the second adhesive layer 108b can be characterized as residing on perimeter surfaces of the transparent lid 106. The third adhesive layer 108c can be characterized as filling spaces, e.g., spaces between inner sidewalls 112 of the package 102 and sidewalls 109 of the transparent lid 106, and spaces between inner sidewalls 112 of the package 102 and the securing frame 110.

In some implementations, the securing frame 110 and the transparent lid 106 are disposed within a recessed area of the package 102. The securing frame 110, e.g., a perimeter frame, provides additional security for the bond between the transparent lid 106 and the package 102. The securing frame 110 bonds to the transparent lid 106, and to the inner sidewall 112 of the package 102. The securing frame 110 is disposed on top of at least a portion of the perimeter of the transparent lid 106 to hold, e.g., lock, the transparent lid 106 in place between the securing frame 110 and the package 102. The securing frame 110 is positioned on the optically transparent lid such that the optically transparent lid is fixedly coupled between the perimeter frame and the package.

In some implementations, the securing frame 110 is a rigid, securing perimeter feature attached to upper sidewalls, e.g., vertical sidewalls, of the package 102 using the third adhesive layer 108c. The securing frame 110 is also attached to, and covers, at least a portion of the perimeter of an upper surface of the transparent lid 106, using the second adhesive layer 108b. The shape of the securing frame 110 conforms to the upper portion of the inner sidewall 112, so that the securing frame 110 has a substantially rectangular profile as seen in the cross-sectional view. In some implementations, the securing frame 110 can be made from injection molded material such as a hardened liquid crystal polymer (LCP). In some implementations, the securing frame 110 can have dimensions in a range of about 1 mm to about 25 mm, and a thickness in a range of about 0.2 mm to about 3.0 mm.

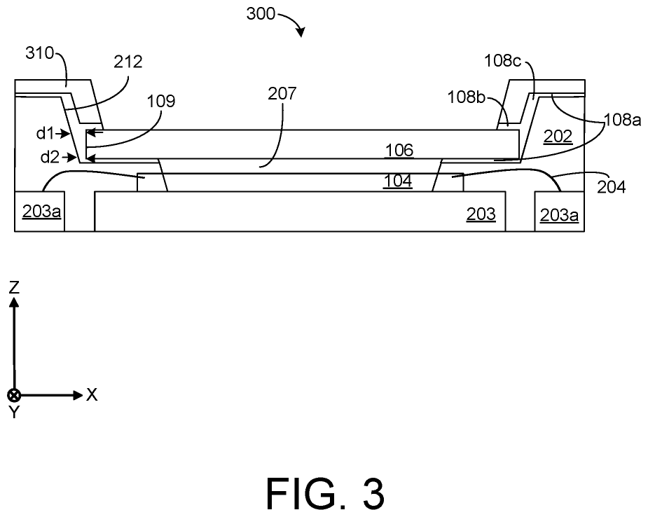

FIG. 2 is a cross-sectional view of an optical sensor module 200, equipped with a package 202 and a securing frame 210, in accordance with some implementations of the present disclosure. The optical sensor module 200 includes the sensor die 104, an air gap 207, the transparent lid 106, and the adhesive layer 108.

The optical sensor module 200, as shown in FIG. 2, further includes several elements that were omitted, for clarity, from the cross-sectional view of the optical sensor module 100 shown in FIG. 1A. For example, FIG. 2 further illustrates a lead frame 203 and wire bonds 204. In some implementations, the lead frame 203 can be cut or stamped from a thin, rolled sheet of metal, e.g., copper. The lead frame 203 can include a base and leads, e.g., contact pads 203a, disposed around a perimeter of the lead frame 203. The sensor die 104 is coupled to, e.g., disposed on top of, above, and/or in contact with, the base of the lead frame 203. The wire bonds 204 can extend from the contact pads 203a to interconnect layers in an upper surface of the sensor die 104. The interconnect layers may be metal layers, e.g., metal pads or patterned metal layers that form wire interconnects. For example, an upper surface of the sensor die 104 can include an interconnect layer that provides signal paths, e.g., metal lines, or optical fiber connectors, to underlying devices. In some implementations, the back side of the sensor die 104 can support solder balls that are in contact with a lower surface, e.g., a layer of metallization on the back side of the sensor die 104. In some implementations, solder balls can be used to mount the sensor die 104 to the lead frame 203. Other methods of bonding the sensor die 104 to the lead frame 203 can be used instead of solder balls, such as, for example, direct bonding.

The wire bonds 204 provide electrical connections, e.g., data transmission paths, between circuit elements on the sensor die 104 and external electronic devices, e.g., electronic devices that may process or store image information sensed by the sensor die 104. The wire bonds 204 can be supported and protected by the package 202, which surrounds the wire bonds 204, the sensor die 104, and at least portions of the sidewalls of the transparent lid 106.

In the optical sensor module 200, the package 202, the air gap 207, and the securing frame 210 have alternative shapes to their counterparts in the optical sensor module 100 shown in FIG. 1A. The optical sensor module 200 shown in FIG. 2 differs from the optical sensor module 100 shown in FIG. 1A in that the inner sidewalls 212 of the package 202 are sloped instead of vertical, whereas the sidewalls of the transparent lid 106 are vertical. Consequently, a distance d1 between the top of the transparent lid 106 and the inner sidewall 212 is greater than a distance d2 between the bottom of the transparent lid 106 and the inner sidewall 212. That is, the sidewalls of the transparent lid 106 are non-parallel to the inner sidewalls 212 of the package 202. The package 202 is made of a packaging material, e.g., a pre-molded epoxy or a ceramic that conforms to the lead frame 203, the transparent lid 106, and the securing frame 110. The shape of the securing frame 210 conforms to the sidewall 212, so that the securing frame 210 has a trapezoidal profile that is parallel to the sloped inner sidewall 212, instead of the rectangular profile of the securing frame 110. Further, in the example shown in FIG. 2, the inner sidewalls 212 of the package 202 extend laterally inward under the transparent lid 106, so as to form an extended shelf supporting the transparent lid 106, and to overlap edges of the sensor die 104 so that the package 202 fully surrounds and supports the wire bonds 204. Consequently, the cavity is reduced to a space between the transparent lid 106 and the sensor die 104, e.g., to the gap 207. In some implementations, the gap 207 is tapered such that the gap 207 has a trapezoidal profile defined by the sloped lower portion of the sidewall 212. As in the example shown in FIG. 1A, the adhesive layer 108 extends around the sides and bottom of the transparent lid 106, and around the sides and bottom of the securing frame 210, so that the adhesive layer 108, e.g., the third adhesive layer 108c, fills the space between the sidewall 212 and the securing frame 210, the space between sidewall 212 and the transparent lid 106, and the space between the securing frame 210 and the transparent lid 106. In some implementations, the thickness of the adhesive layer 108 can be in a range of about 0.2 mm to about 3.0 mm.

FIG. 3 is a cross-sectional view of an optical sensor module 300 equipped with a securing frame 310, in accordance with some implementations of the present disclosure. The optical sensor module 300 includes the package 202, the lead frame 203, the contact pads 203a, the wire bonds 204, the sensor die 104, the air gap 207, the transparent lid 106, the adhesive layer 108, and a securing frame 310.

The optical sensor module 300 shown in FIG. 3 differs from the optical sensor module 200 shown in FIG. 2 in that the securing frame 310 differs from the securing frames 110 and 210. In the optical sensor module 300, the securing frame 310 has an alternative shape to its counterpart in the optical sensor module 100 shown in FIG. 1A. In the example shown in FIG. 3, the package 202 has the same sidewall profile, as is shown in FIG. 2, where a top portion of the sidewall 212 is sloped and the package 202 extends under the transparent lid 106. However, the securing frame 310 extends outward to cover a top perimeter of the package 202 so that the securing frame 310 has an L-shaped profile. The L-shaped profile is conformal with, e.g., parallel to, the inner sidewalls 212 of the package 202. The adhesive layer 108 also extends across a top surface of the package 202 to bond the securing frame 310 to the package 202. The securing frame 310 extending over the top of the package 102 further increases the adhesion strength of the adhesive layer 108. In addition, the longer seal creates a longer path length for moisture and gas penetration into the air gap 207.

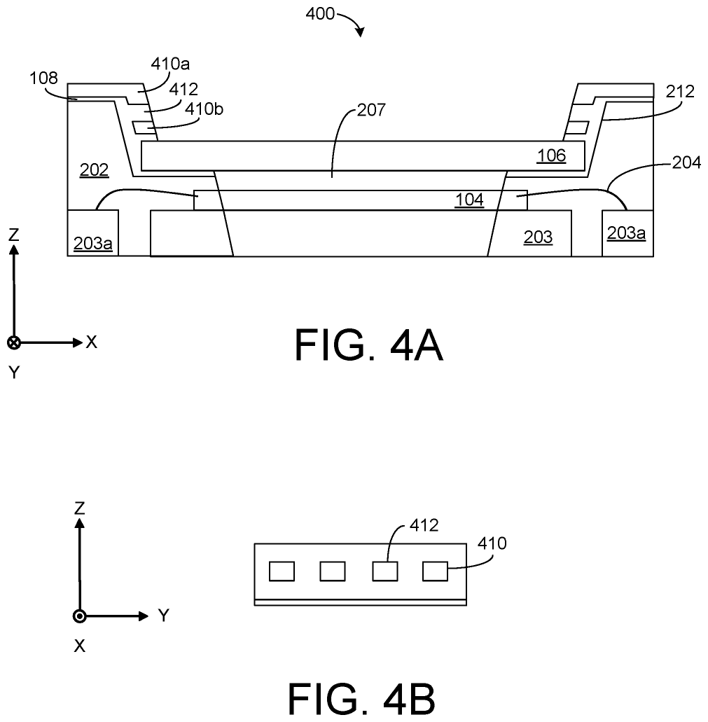

FIG. 4A is a cross-sectional view of an optical sensor module 400, equipped with a securing frame 410 (in two parts, 410a and 410b), in accordance with some implementations of the present disclosure. FIG. 4B is a side elevation view of the securing frame 410 along the sloped upper portion of the sidewall 212. The optical sensor module 400 includes the package 202, the lead frame 203, the contact pads 203a, the wire bonds 204, the sensor die 104, the air gap 207, the transparent lid 106, and the adhesive layer 108.

In the optical sensor module 400, the securing frame 410 differs from the securing frame 310 shown in FIG. 3. In the example shown in FIGS. 4A and 4B, the securing frame 410 has an L-shaped profile, similar to that of the securing frame 310. However, the securing frame 410 is discontinuous, e.g., the securing frame 410 can be patterned to include cut-outs, or securing holes 412. As seen in the cross-sectional view of FIG. 4A, the securing frame 410 appears to include two portions, an upper portion 410a and a lower portion, 410b, separated by the securing hole 412.

FIG. 4B shows the plane in which the securing holes are formed. In some implementations, the securing holes 412 can be arranged in an array, e.g., a linear array, or a matrix. In some implementations, the securing holds 412 are rectangular in shape and spaced apart according to a pitch p, wherein the pitch p defines a distance between repeating features of the array. The securing hole 412 is configured to receive, e.g., be filled by, epoxy, e.g., the adhesive layer 108. The securing holes 412 provide a sort of keying feature that increases the strength of the bond between the securing frame 410 and the package 202, thereby increasing mechanical stability of the structure securing the position of the transparent lid 116.

As in the previous examples shown in FIG. 1A, FIG. 2, and FIG. 3, the adhesive layer 108 extends around the sides and bottom of the transparent lid 106, and around the sides and bottom of the securing frame 210, so that the adhesive layer 108 fills the space between the sidewall 212 and the securing frame 210, the space between sidewall 212 and the transparent lid 106, and the space between the securing frame 210 and the transparent lid 106.

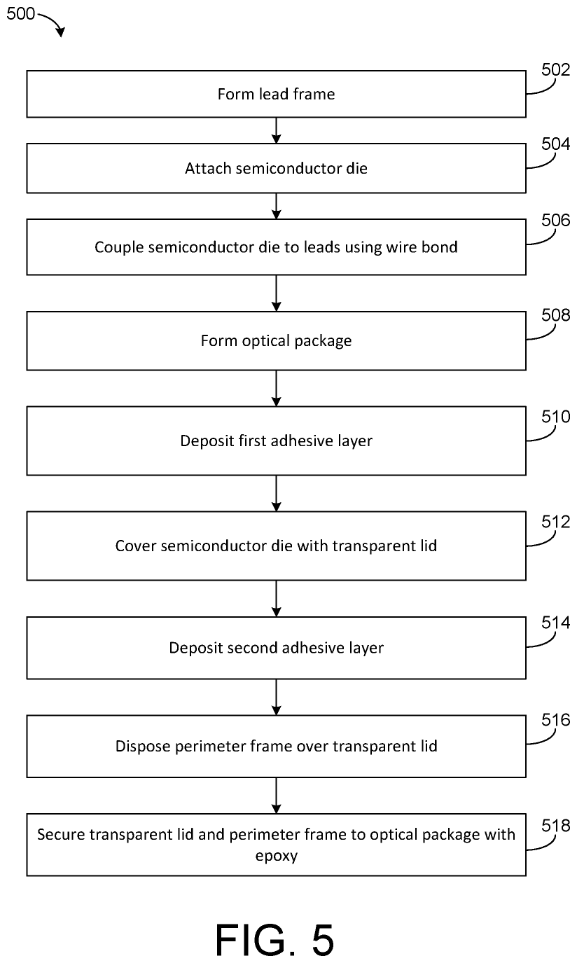

FIG. 5 is a flow chart illustrating a method 500 for fabricating the optical sensor module 100, in accordance with some implementations of the present disclosure. Operations 502-514 of the method 500 can be carried out to form an optical sensor module, e.g., the optical sensor module 100 200, 300, or 400, according to some implementations as described below with respect to FIG. 1A, FIG. 1B, FIG. 2, FIG. 3, FIG. 4A, and FIG. 4B. Operations of the method 500 can be performed in a different order, or not performed, depending on specific applications. It is noted that the method 500 may not produce a complete optical sensor module 100. Accordingly, it is understood that additional processes can be provided before, during, or after method 500, and that some of these additional processes may be briefly described herein.

At 502, the method 500 includes forming a lead frame, e.g., the lead frame 203, according to some implementations as shown in FIG. 2. The lead frame 203 can be formed as a rolled copper sheet that can be patterned, or cut, to provide features such as the contact pads 203a. In some implementations, the lead frame 203 can have a thickness in a range of about 0.1 mm to about 0.5 mm.

At 504, the method 500 includes attaching a semiconductor die, e.g., the (optical) sensor die 104, to the lead frame 203, according to some implementations as shown in FIG. 2. The sensor die 104 can be attached to the lead frame 203 using solder, or by applying an adhesive, e.g., an epoxy or an adhesive film such as, for example, a polyimide tape.

At 506, the method 500 includes coupling the semiconductor die, e.g., the sensor die 104, to the contact pads 203a by the wire bonds 204, according to some implementations as shown in FIG. 2. The wire bonds 204 can be made of aluminum, copper, gold, or any other suitable metal or metal alloy. The wire bonds 204 can be secured to the contact pads 203a by soldering, for example.

At 508, the method 500 includes forming the package 202, according to some implementations as shown in FIG. 2. The package 202 can be formed by, e.g., injection molding in which a fluid insulating material, such as a molding compound or a ceramic, is injected into a mold so as to flow around the wire bonds 204 and to fill in spaces between the contact pads 203a and other surface features of the lead frame 203. Alternatively, the package 202 can be pre-molded into the shape shown in FIG. 2 and then attached to the lead frame 203.

At 510, the method 500 includes depositing a first adhesive layer 108a onto the package 202, according to some implementations as shown in FIG. 2. In particular, the first adhesive layer 108a can be formed on lower horizontal surfaces of the package 202 where the transparent lid 106 will rest. In some implementations, e.g., for the optical sensor module 300 and the optical sensor module 400, the first adhesive layer 108a can additionally be formed on upper horizontal surfaces of the package 202 where an L-shaped securing frame, e.g., the securing frame 310 or the securing frame 410 will rest. In some implementations, the first adhesive layer 108a can be an adhesive film that is deposited onto the horizontal surfaces of the package 202. In some implementations, the first adhesive layer 108a can be an epoxy that can be dispensed onto horizontal surfaces of the package 202.

At 512, the method 500 includes covering the semiconductor die, e.g., the sensor die 104, with a protective transparent lid, e.g., the transparent lid 106, according to some implementations as shown in FIGS. 1A, 2, 3, and 4A. In some implementations, the transparent lid 106 can be formed from a glass substrate, e.g., a glass wafer or a sapphire wafer that, when patterned and singulated, will form a plurality of transparent lids 106. Singulation may include a process of cutting, sawing, or scoring the glass substrate along singulation cut lines, e.g., along singulation boundaries, to separate square sections of the glass substrate, thus forming individual transparent lids 106 . . . . The singulation technique used for a glass substrate can be similar to that used to singulate a semiconductor wafer into individual dies or chips. In some implementations, a transparent polymer substrate can be substituted for the glass substrate. If the transparent substrate used is made of a polymer material, a different or modified singulation technique may be employed to achieve a clean cut along the singulation boundaries Edges of the transparent lid 106 can rest on the horizontal perimeter surfaces of the package 202 so as to suspend the transparent lid 106 above the sensor die 104 so that the transparent lid 106 and the sensor die 104 are separated by a gap, e.g., the rectangular gap 107 or the trapezoidal gap 207. The first adhesive layer 108 will serve to hold the transparent lid 106 in place until the securing frame 210 is attached.

At 514, the method 500 includes depositing a second adhesive layer 108b, according to some implementations as shown in FIG. 2. The second adhesive layer 108b can be deposited onto top perimeter surfaces of the transparent lid 106. In some implementations, the second adhesive layer 108b can be an adhesive film. In some implementations, the second adhesive layer 108b can be an epoxy.

At 516, the method 500 includes attaching the securing frame 210, according to some implementations as shown in FIG. 2. In some implementations, the securing frame, e.g., the securing frame 210, 310, or 410, can be formed by injection molding. The molding material can be, for example, a liquid crystal polymer. The securing frame 210 is a rigid frame that rests on the second adhesive layer 108b and is spaced apart from the sidewalls 212 of the package 202. In some implementations, the securing frame 210 is a perimeter frame that wraps around the entire perimeter of the transparent lid 106. In some implementations, the securing frame 210 is a perimeter frame that wraps around a portion, or portions, of the perimeter of the transparent lid 106. In some implementations, e.g., for the optical sensor module 300 that includes an L-shaped securing frame, e.g., the securing frame 310, the securing frame is attached to the first adhesive layer 108a on top surfaces of the package 202 as well as to the second adhesive layer 108b on top perimeter surfaces of the transparent lid 106, as shown in FIG. 3. In some implementations, e.g., for the optical sensor module 400 that includes an L-shaped securing frame, e.g., the securing frame 410, the securing frame is attached to the first adhesive layer 108a on top surfaces of the package 202 as well as to the first adhesive layer 108a on top perimeter surfaces of the transparent lid 106, as shown in FIG. 4A. In some implementations, the securing frame 210 is patterned to form securing holes 412, as shown in FIG. 4B, prior to attaching the securing frame 210 to the package 202.

At 518, the method 500 includes injecting a third adhesive layer 108 into diagonal spaces between the sidewall 212 and the securing frame 210, according to some implementations as shown in FIG. 2. The third adhesive layer 108c also fills remaining spaces between the sloped sidewalls 212 of the package 202 and vertical side surfaces of the transparent lid 106. The third adhesive layer thus secures the transparent lid 106 and the securing frame 210 to the package 202.

In some implementations, the first, second, and third adhesive layers 108a,b,c can be cured to harden the adhesive materials after the optical sensor module structure is complete. In some implementations, the cure operation can be accomplished by applying a thermal treatment to the that includes heating the adhesive layer(s) 108 to a temperature of at least 70 degrees C. Additionally or alternatively, the cure operation for some compositions of the adhesive layer(s) 108 may include exposure to ultraviolet (UV) light.

As described above, an optical sensor module can include structural elements that allow light into an image sensor die while blocking moisture from reaching the image sensor die. A transparent lid mounted above the image sensor die provides protection for the die, while a securing frame mounted above the transparent lid maintains the position of the transparent lid. Multiple bonding surfaces serve to increase adhesion strength between the securing frame, the transparent lid, and the surrounding package. Meanwhile, a pre-molded package provides support around a perimeter of the transparent lid while anchoring the securing frame.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a lead frame;
a semiconductor die coupled to the lead frame;
an optically transparent lid spaced apart from the semiconductor die by a gap;
a package surrounding the semiconductor die, the package configured to support a perimeter of the optically transparent lid, coupled thereto by a sealant; and
a perimeter frame disposed on top of at least a portion of the perimeter of the optically transparent lid such that the optically transparent lid is fixedly coupled between the perimeter frame and the package.

2. The apparatus of claim 1, wherein the semiconductor die includes an optical sensor.

3. The apparatus of claim 2, wherein the optical sensor is a silicon photomultiplier.

4. The apparatus of claim 2, wherein the optical sensor includes a micro-lens array.

5. The apparatus of claim 1, wherein the perimeter frame is coupled to a sidewall of the package by the sealant.

6. The apparatus of claim 1, wherein the sealant is further disposed between the perimeter frame and the optically transparent lid.

7. The apparatus of claim 1, wherein the perimeter frame and the optically transparent lid are disposed within a recessed area of the package.

8. The apparatus of claim 6, wherein the perimeter frame includes a hardened liquid crystal polymer.

9. The apparatus of claim 1, wherein the sealant includes an organic epoxy material.

10. A method, comprising:
forming a lead frame having a base and leads;
attaching a semiconductor die to the base;
coupling the semiconductor die to the leads using wire bonds;
forming an optical package around the lead frame, the semiconductor die, and the wire bonds;
covering the semiconductor die with a glass lid;
disposing a perimeter frame over the glass lid; and
securing the glass lid and the perimeter frame to the optical package.

11. The method of claim 10, wherein disposing the perimeter frame includes securing the perimeter frame to the glass lid with an adhesive layer.

12. The method of claim 10, wherein forming the optical package includes a pre-molding process.

13. The method of claim 10, wherein covering the semiconductor die with the glass lid includes forming an air gap between the semiconductor die and the glass lid.

14. The method of claim 10, wherein securing the glass lid and the perimeter frame to the optical package includes sealing using a layer of epoxy.

15. The method of claim 10, wherein securing the glass lid and the perimeter frame to the optical package lengthens a moisture penetration path to the air gap.

16. A die package, comprising:
a lead frame;
a glass lid suspended above the lead frame;
a perimeter frame over the glass lid; and
a packaging material configured to be conformal with the lead frame, the glass lid, and the perimeter frame.

17. The die package of claim 16, further comprising a sealant between the perimeter frame, the glass lid, and the packaging material.

18. The die package of claim 17, wherein the perimeter frame includes securing holes to receive the sealant.

19. The die package of claim 16, wherein the packaging material includes at least one of a pre-molded epoxy or a ceramic.

20. The die package of claim 16, wherein the perimeter frame is made of a rigid material.
